(19) United States
(12) Patent Application Publication
(10) Pub. No.: US 2024/0355724 A1
(43) Pub. Date: Oct. 24, 2024

(54) SEMICONDUCTOR DEVICE AND POWER CONVERSION APPARATUS

(71) Applicant: Mitsubishi Electric Corporation, Tokyo (JP)

(72) Inventor: Tatsuya KAWASE, Tokyo (JP)

(73) Assignee: Mitsubishi Electric Corporation, Tokyo (JP)

(21) Appl. No.: 18/683,431

(22) PCT Filed: Oct. 25, 2021
(86) PCT No.: PCT/JP2021/039233

§ 371 Date: Feb. 13, 2024

(51) Int. Cl. H01L 23/498; H01L 23/00; H01L 23/15; H01L 23/373; H01L 25/18

(52) U.S. Cl. CPC H01L 23/49838; H01L 23/15; H01L 23/373; H01L 23/49822; H01L 24/32; H01L 24/29; H01L 24/30; H01L 24/48; H01L 24/73; H01L 24/83; H01L 25/18; H01L 2224/29111; H01L 2224/3003; H01L 2224/32225; H01L 2224/48137; H01L 2224/48153; H01L 2224/73265; H01L 2224/83801; H01L 2924/1203; H01L 2924/13055; H01L 2924/13091

(57) ABSTRACT

A semiconductor device includes a first insulating material, a first conductor pattern provided on an upper surface of the first insulating material, a second conductor pattern provided on a lower surface of the first insulating material, a semiconductor element bonded to an upper surface of the first conductor pattern by a first bonding material, and a first base plate bonded to a lower surface of the second conductor pattern by a second bonding material, in which a ratio κ₁/D₁ satisfies κ₁/D₁≤35×10⁴W/(m²K) where κ₁ represents thermal conductivity of the first insulating material and D₁ represents a thickness of the first insulating material, solidus temperature of the first bonding material is equal to or higher than solidus temperature of the second bonding material, and a difference between the solidus temperature of the first bonding material and the solidus temperature of the second bonding material is within 40° C.

### TECHNICAL FIELD

The present disclosure relates to a semiconductor device, a power conversion apparatus, and a method of manufacturing the semiconductor device.

### BACKGROUND ART

Patent Document 1 describes a molded semiconductor device. Patent Document 1 describes that due to being small in size, having excellent reliability, and being easy to handle, a molded semiconductor device in particular is in wide use in controlling air conditioning apparatus and the like.

### PRIOR ART DOCUMENTS

### Patent Document(s)

[Patent Document 1] Japanese Patent Application Laid-Open No. 2015-115382

### SUMMARY

### Problem to be Solved by the Invention

In the process of manufacturing a semiconductor device, a problem lies in that the bonding material re-melts, leading to the deterioration in quality of the semiconductor device.

The present disclosure is intended to solve such a problem, and an object thereof is to provide a semiconductor device that can suppress re-melting of the bonding material during the manufacturing process and suppress deterioration in quality due to re-melting of the bonding material.

### Means to Solve the Problem

According to the present disclosure, a semiconductor device includes a first insulating material having an upper surface and a lower surface, a first conductor pattern provided on the upper surface of the first insulating material, a second conductor pattern provided on the lower surface of the first insulating material, a semiconductor element bonded to an upper surface of the first conductor pattern by a first bonding material, and a first base plate bonded to a lower surface of the second conductor pattern by a second bonding material, in which a ratio κ₁/D₁ satisfies κ₁/D₁≤35×10⁴W/(m²K) where κ₁ represents represents thermal conductivity of the first insulating material and D₁ represents a thickness of the first insulating material, solidus temperature of the first bonding material is equal to or higher than solidus temperature of the second bonding material, and a difference between the solidus temperature of the first bonding material and the solidus temperature of the second bonding material is within 40° C.

### Effects of the Invention

According to the present disclosure, the semiconductor device that can suppress re-melting of the bonding material during the manufacturing process and suppress deterioration in quality due to re-melting of the bonding material is provided.

The objects, characteristics, aspects, and advantages of the technique disclosed in the present specification will become more apparent from the following detailed description and the accompanying drawings.

### BRIEF DESCRIPTION OF DRAWINGS

FIG. 1 A cross-sectional view of a semiconductor device of Embodiment 1.

FIG. 2 A top view of the semiconductor device of Embodiment 1.

FIG. 3 A cross-sectional view of a semiconductor device of Embodiment 2.

FIG. 4 A cross-sectional view of the semiconductor device of Embodiment 2.

FIG. 5 A top view of the semiconductor device of Embodiment 2.

FIG. 6 A cross-sectional view of a semiconductor device of Embodiment 3.

FIG. 7 A cross-sectional view of the semiconductor device of Embodiment 3.

FIG. 8 A cross-sectional view of a semiconductor device of Embodiment 4.

FIG. 9 A cross-sectional view of a semiconductor device of Embodiment 5.

FIG. 10 A flowchart illustrating a method of manufacturing the semiconductor device of Embodiment 1.

FIG. 11 A block diagram illustrating a configuration a power conversion system to which a power conversion apparatus is applied of Embodiment 6.

### DESCRIPTION OF EMBODIMENT(S)

In the following description, the terms “up” and “down” refer to one direction of a semiconductor device as the upward direction and the opposite direction thereof as the downward direction, and are not intended to limit the vertical direction of the semiconductor device during manufacturing or using thereof.

### A. Embodiment 1

### A-1. Configuration

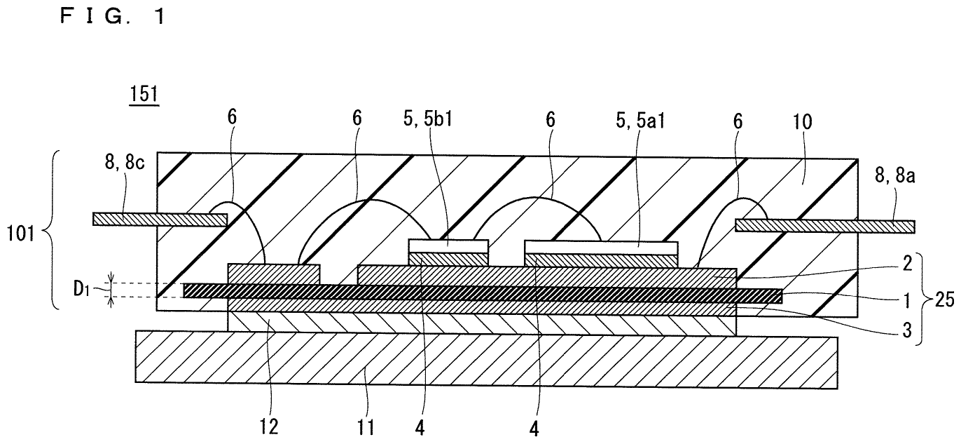

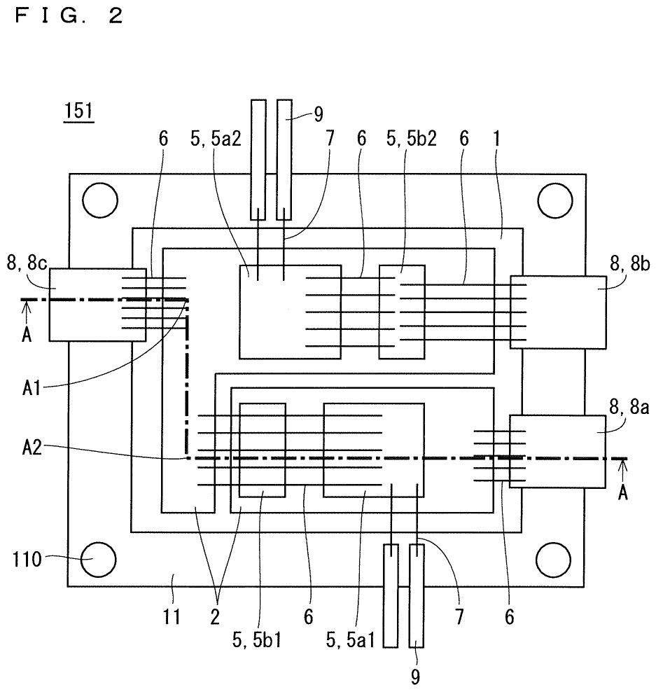

FIG. 2 is a top view of a semiconductor device 151. In order to illustrate the internal structure of the semiconductor device 151, a sealing material 10 included in the semiconductor device 151 is omitted in FIG. 2. FIG. 1 is a cross-sectional view of the semiconductor device 151 of Embodiment 1 and is a cross-sectional view taken along the line A-A in FIG. 2.

The semiconductor device 151 includes a semiconductor unit 101, a base plate 11 (an example of a first base plate), and a bonding material 12 (an example of a second bonding material).

The semiconductor unit 101 includes an insulating substrate 25, a bonding material 4 (an example of a first bonding material), a semiconductor element 5a1, a semiconductor element 5a2, a semiconductor element 5b1-, a semiconductor element 5b2, a wire 6, a wire 7, a main terminal 8a, a main terminal 8b, a main terminal 8c, a signal terminal 9, and the sealing material 10.

The semiconductor element and the semiconductor element 5a2 are Si Insulated Gate Bipolar Transistors (IGBTs), and the semiconductor element 5b1 and the semiconductor element 5b2 are Si diodes. When the semiconductor element 5a1, the semiconductor element 5a2, the semiconductor element 5b1, and the semiconductor element 5b2 do not need to be specific, the semiconductor element 5a1, the semiconductor element 5a2, the semiconductor element 5b1, and the semiconductor element 5b2 are also referred to as the semiconductor element 5, respectively.

Instead of including the IGBTs and the diodes, the semiconductor device 151 may include a Reverse-Conducting IGBT (RC-IGBT) in which an IGBT and a diode are integrated. Also, instead of Si IGBTs and Si diodes, the semiconductor device 151 may include, for example, a SiC or GaN Metal Oxide Semiconductor Field Effect Transistor (MOSFET) and a SiC or GaN SBD.

When not need to be specific, the main terminal 8a, the main terminal 8b, and the main terminal 8c are also referred to as the main terminals 8, respectively. Each main terminal 8 is a power terminal.

The insulating substrate 25 includes an insulating material 1 (an example of a first insulating material) having an upper surface and a lower surface, a conductor pattern 2 (an example of a first conductor pattern) provided on the upper surface of the insulating material 1, and a conductor pattern 3 (an example of a second conductor pattern) provided on the lower surface of the insulating material 1. The insulating material 1 and the conductor pattern 2 are bonded to each other by direct bonding, for example. The insulating material 1 and the conductor pattern 3 are bonded to each other by direct bonding, for example.

Each semiconductor element 5 is bonded to the upper surface of the conductor pattern 2 by the bonding material 4.

A wire 6 is a power wire. As illustrated in FIG. 2, the semiconductor element 5a1 and the semiconductor element 5b1, the semiconductor element 5b1 and the conductor pattern 2, the conductor pattern 2 and the main terminal 8a, the conductor pattern 2 and the main terminal 8c, the semiconductor element 5a2 and the semiconductor element 5b2, the semiconductor element 5b2 and the main terminal 8b are connected by the wires 6.

A wire 7 is a signal wire. The semiconductor element 5a1 and the signal terminals 9, and the semiconductor element 5a2 and the signal terminals 9 are connected by the wires 7.

In the semiconductor unit 101, the sealing material 10 seals the insulating material 1, the conductor pattern 2, a portion of the conductor pattern 3, the bonding materials 4, the semiconductor elements 5, the wires 6, the wires 7, portions of the main terminals 8, and portions of the signal terminals 9. In the semiconductor unit 101, the lower surface of the conductor pattern 3 is exposed from the sealing material 10.

The semiconductor unit 101 is mounted on the upper surface of base plate 11 via the bonding material 12. The base plate 11 is bonded to the lower surface of the conductor pattern 3 by the bonding material 12.

The insulating material 1 is, for example, an insulating resin. The insulating resin is, for example, an insulating resin whose main component is epoxy resin. The insulating material 1 is, for example, ceramic. The ceramic is, for example, a ceramic whose main component is Al₂O₃.

For heat dissipation enhancement, the higher the thermal conductivity of the insulating material 1 the more suitable, and the thinner the insulating material 1 the more suitable. While the heat applied to the semiconductor unit 101 from the lower side of the semiconductor unit 101 is easily transmittable to the bonding material 4 during the manufacturing process with the insulating material 1 of high thermal conductivity and thin, transmitting excessive heat to the bonding material 4 leads to a problem of re-melting of the bonding material 4. In order to suppress re-melting of the bonding material 4 during the manufacturing process, it is desirable that the ratio κ₁/D₁ to satisfy κ₁/D₁≤35×10⁴W/(m²K) where κ₁ represents the thermal conductivity of the insulating material 1 and D₁ represents the thickness of the insulating material 1 (see FIG. 1). For example, the thermal conductivity κ₁ of the insulating material 1 is 35 W/(m·K) or less, and the thickness D₁ of the insulating material 1 is 100 μm or more. By setting the thickness D₁ of the insulating material 1 to 100 μm or more, the insulation performance and strength of the insulating material 1 are improved compared to when the thickness D₁ of the insulating material 1 is less than 100 μm. With the use of an insulating resin as the insulating material 1, the thermal conductivity of the insulating material 1 is made easier to lower, making re-melting of the bonding material 4 easier to suppress.

The material of the conductor pattern 2 is, for example, metal. The metal is, for example, aluminum, an aluminum alloy, copper, or a copper alloy.

The conductor pattern 2 is in contact with the semiconductor element 5 via the bonding material 4. The conductor pattern 2 has a function of diffusing heat the semiconductor element 5 generates. It is preferable that the conductor pattern 2 has a sufficient thickness so that the heat the semiconductor element 5 generates can be sufficiently diffused in the in-plane direction. The desirable thickness of the conductor pattern 2, which depends on the in-plane layout of the conductor pattern 2, is, for example, 0.4 mm to 1.2 mm.

The adhesion between the conductor pattern 2 and the sealing material 10 can be improved by providing irregularities such as dimples or slits on the upper surface of the conductor pattern 2.

The material of the conductor pattern 3 is, for example, metal. The metal is, for example, aluminum, an aluminum alloy, copper, or a copper alloy.

The bonding material 4 is, for example, solder. The bonding material 4 is, for example, lead-free solder containing Sn as a main component.

Although FIG. 2 illustrates a case where the semiconductor device 151 includes four semiconductor elements, the semiconductor device 151 may include one, two, three, or five or more semiconductor elements.

The material of the wire 6 is, for example, aluminum, an aluminum alloy, copper, or a copper alloy.

A wire made of a combination of aluminum and copper, for example, a wire made of a composite material in which the outer periphery is aluminum and the inside is copper may be adopted to the wire 6.

Although it depends on the current capacity required of the wire 6, a desirable diameter of the wire 6 is, for example, 200 μm to 1000 μm. The current capacity can be increased by using a ribbon-shaped wire that is wide in the direction perpendicular to the extending direction as the wire 6.

The material of the wire 7 is, for example, aluminum, an aluminum alloy, copper, or a copper alloy. The diameter of the wire 7 may be smaller than the diameter of the wire 6 because, unlike the wire 6, there is no need to flow a large current through the wire 7. The diameter of the wire 7 is, for example, 100 μm to 400 μm.

The material of the main terminal 8 is, for example, copper or a copper alloy. For weight reduction, aluminum or an aluminum alloy may be used as the material of the main terminal 8. Self-heating of the main terminal 8 when current flows through the main terminal 8 can be suppressed by making the main terminal 8 thicker. A desirable thickness of the main terminal 8 is, for example, 0.5 mm to 2.0 mm.

The material of the signal terminal 9 is, for example, copper or a copper alloy. For weight reduction, aluminum or an aluminum alloy may be used as the material of the signal terminal 9. Similar to the wire 7, there is no need to flow a large current through the signal terminal 9. Therefore, a thickness of about 1 mm is sufficient for the signal terminal 9.

The sealing material 10 is, for example, a resin. The resin is, for example, epoxy resin.

The heat the semiconductor element 5 generates raises temperature of the sealing material 10. For suppressing fluctuations in the linear thermal expansion coefficient of the sealing material 10 due to the temperature rise, the desirable glass transition temperature Tg of the sealing material 10 is, for example, 175° C. or higher.

For suppressing peeling between the sealing material 10 and the conductor pattern 2 and suppressing cracks in the bonding material 12, a desirable value for the linear thermal expansion coefficient of the sealing material 10 is, for example, 18 to 24 ppm/° C. The linear thermal expansion coefficient of the sealing material 10 being equal to or less than the linear thermal expansion coefficient of the bonding material 12 reduces the stress generated in the bonding material 12, improving the reliability of the semiconductor device 151. When the sealing material 10 undergoes a glass transition, the linear thermal expansion coefficient indicates the linear thermal expansion coefficient at a temperature equal to or lower than the glass transition temperature Tg of the sealing material 10. The linear thermal expansion coefficient of the sealing material 10 can be adjusted by adjusting the filler in the sealing material 10.

The bonding material 12 is, for example, solder. The bonding material 12 is, for example, lead-free solder containing Sn as a main component.

By making the bonding material 12 thinner, the amount of heat required to melt the bonding material 12 during manufacturing can be reduced, reducing manufacturing costs. Also, by making the bonding material 12 thinner, the thermal resistance of the bonding material 12 can be suppressed. The thickness of the bonding material 12 is, for example, 150 μm or less.

The solidus temperature of the bonding material 4 is equal to or higher than the solidus temperature of the bonding material 12, and the difference between the solidus temperature of the bonding material 4 and the solidus temperature of the bonding material 12 is within 40° C.

It is desirable that the material of the base plate 11 has high thermal conductivity. The material of the base plate 11 is, for example, aluminum, an aluminum alloy, copper, or a copper alloy. A desirable thickness of the base plate 11 is, for example, 2 mm to 4 mm from the viewpoint of heat diffusion and rigidity.

When the material of the base plate 11 is copper or a copper alloy, oxidation and corrosion of the base plate 11 can be suppressed if the surface of the base plate 11 is coated with plating such as Ni plating.

As illustrated in FIG. 2, the base plate 11 is provided with holes 110 for attaching the semiconductor device 151 to a cooler or the like. The base plate 11 does not need to be provided with the holes 110.

The lower surface of the base plate 11 is flat, for example, as illustrated in FIG. 1. When the semiconductor device 151 is used, heat is generated due to loss in the semiconductor elements 5. The semiconductor device 151 is attached to a cooler via a Thermal Interface Material (TIM) such as grease, and is cooled. The cooler may be air-cooled or water-cooled. The semiconductor device 151 may be a device including a cooler.

For high current density and high integration of the semiconductor device 151, the heat dissipation efficiency from the semiconductor elements 5 is desirably high. In the semiconductor device 151, the base plate 11 being attached to the semiconductor unit 101 improves the efficiency of heat dissipation from the semiconductor elements 5. This allows for the semiconductor device 151 to achieve high current density and high integration even if the cooler attached to the semiconductor device 151 is an air-cooled cooler and the cooling performance of the cooler is low.

In the semiconductor device 151 of Embodiment 1, the solidus temperature of the bonding material 4 is equal to or higher than the solidus temperature of the bonding material 12, and, the ratio κ₁/D₁, where κ₁ represents the thermal conductivity of the insulating material 1 and D₁ represents the thickness of the insulating material 1, satisfies κ₁/D₁≤35×10⁴W/(m²K); therefore, re-melting of the bonding material 4 due to heating when bonding the base plate 11 to the semiconductor unit 101 is suppressed, suppressing deterioration in quality of the semiconductor device 151 due to re-melting of the bonding material 4.

### A-2. Manufacturing Method

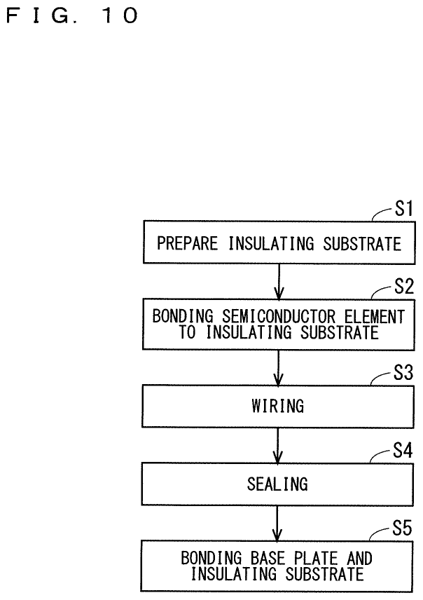

FIG. 10 is a flowchart illustrating a method of manufacturing the semiconductor device of Embodiment 1.

First, in Step S1, the insulating substrate 25 is prepared. As described above, the insulating substrate 25 is an insulating substrate including the insulating material 1, the conductor pattern 2 provided on the upper surface of the insulating material 1, and the conductor pattern 3 provided on the lower surface of the insulating material 1.

Next, in Step S2, each semiconductor element 5 is bonded onto the upper surface of the conductor pattern 2 of the insulating substrate 25 using the bonding material 4.

In Step S2, first, the semiconductor elements 5 are placed on the upper surface of the conductor pattern 2 with the bonding material 4 interposed therebetween. Next, the temperature is increased to melt the bonding material 4. Thereafter, by lowering the temperature and solidifying the bonding material 4, each semiconductor element 5 and the conductor pattern 2 are bonded to each other.

After Step S2, wiring using the wires 6 and 7 is performed in Step S3.

In Step S3, first, the wires 6 connect the semiconductor element 5a1 and the semiconductor element 5b1, the semiconductor element 5b1 and the conductor pattern 2, and the semiconductor element 5a2 and the semiconductor element 5b2. Next, the main terminals 8 and the signal terminals 9 are arranged. Then, the signal terminals 9 and the semiconductor element 5a1, and the signal terminals 9 and the semiconductor element 5a2 are connected are connected by the wires 7, also, the main terminal 8a and the conductor pattern 2, the main terminal 8b and the semiconductor element 5b2, and the main terminal 8c and the conductor pattern 2 are connected by the wires 6.

After Step S3, the semiconductor elements 5 are sealed with the sealing material 10 in Step S4.

The semiconductor unit 101 is obtained through Steps S1 to S4.

After Step S4, in Step S5, the lower surface of the conductor pattern 3 and the base plate 11 are bonded by the bonding material 12.

The semiconductor device 151 is obtained through Steps S1 to S5.

In Step S5, after arranging the bonding material 12 between the semiconductor unit 101 and the base plate 11, the temperature of each material is increased to melt the bonding material 12. As a method for efficiently melting the bonding material 12 in a situation where the heat capacity of the semiconductor unit 101 and the base plate 11 is large, there is a method of heating the lower surface of the base plate 11 by bringing a hot plate or the like into contact therewith.

When the bonding material 4 is re-melted in Step S5, the bonding material 4 expands due to the change in state from solid to liquid, causing cracks to occur in the sealing material 10, deteriorating the characteristics and reliability of the semiconductor device 151. Therefore, it is desirable to selectively melt only the bonding material 12 without melting the bonding material 4. However, when heat is applied from the lower surface of the base plate 11, the heat conducts in the semiconductor unit 101 from the lower surface side to the upper surface side, potentially causing the bonding material 4 within the semiconductor unit 101 to re-melt.

Re-melting of the bonding material can also be suppressed by employing a material with a high melting point, such as a sinter bonding material, as the bonding material for bonding the semiconductor elements 5 to the conductor pattern 2. However, in this case, bonding using a sinter bonding material requires the application of pressure, etc., which may require an increase in the size of the manufacturing equipment, or the size of the semiconductor unit 101 may be limited. Further, that would increase direct material costs and manufacturing equipment costs, leading to an increase in the manufacturing cost of the semiconductor device 151. The manufacturing cost of the semiconductor device 151 can be reduced by using solder as the bonding material for bonding the semiconductor elements 5 to the conductor pattern 2.

If the solidus temperature of the bonding material 4 is equal to or higher than the solidus temperature of the bonding material 12, re-melting of the bonding material 4 in

Step S5 is suppressed. If the solidus temperature of the bonding material 4 is equal to or higher than the liquidus temperature of the bonding material 12, re-melting of the bonding material 4 in Step S5 is suppressed. If the solidus temperature of the bonding material 4 is higher than the liquidus temperature of the bonding material 12, re-melting of the bonding material 4 in Step S5 is suppressed.

If the solidus temperature of the bonding material 4 is excessively higher than the solidus temperature of the bonding material 12, it leads to the following problem. In Step S2, the bonding material 4 is solidified at a solidus temperature, and then cooled to room temperature. At room temperature, the conductor pattern 2 and the insulating material 1 directly or indirectly receive a force from the bonding material 4 that is proportional to the difference ΔT1 between the solidus temperature of the bonding material 4 and room temperature due to differences in linear expansion coefficients thereof. Similarly, at room temperature, the conductor pattern 3 and the insulating material 1 directly or indirectly receive a force from the bonding material 12 that is proportional to the difference ΔT2 between the solidus temperature of the bonding material 12 and room temperature. If the difference between ΔT1 and ΔT2 is large, the force applied to the insulating material 1 differs greatly between the upper side and the lower side, causing warpage or local stress in the insulating material 1, reducing the reliability of the semiconductor device 151. Therefore, from the viewpoint of reliability of the semiconductor device 151, the difference between ΔT1 and ΔT2, that is, the difference between the solidus temperature of the bonding material 4 and the solidus temperature of the bonding material 12, is preferably 40° C. or less.

Due to variations in the temperatures of the bonding material 4 and the bonding material 12 during the manufacturing process, fair suppression of re-melting of the bonding material 4 in Step S5 cannot be achieved by simply the solidus temperature of the bonding material 4 being equal to or higher than the solidus temperature of the bonding material 12. By restraining the heat conductivity of insulating material 1, the re-melting of the bonding material 4 in Step S5 can be suppressed. The configuration satisfying κ₁/D₁≤35×10⁴W/(m²K) where κ₁ represents the thermal conductivity of the insulating material 1 and D₁ represents the thickness of the insulating material 1, heat transmitted to the bonding material 4 when heating is performed from the lower surface of the base plate 11 can be suppressed, consequently, re-melting of the bonding material 4 in Step S5 can be suppressed. This increases the allowable temperature variations in the manufacturing process.

By making the conductor pattern 3 thinner than the conductor pattern 2, the heat capacity of the conductor pattern 3 can be lowered, making the heat capacity of the conductor pattern 3 smaller than the heat capacity of the conductor pattern 2, for example. With the heat capacity of the conductor pattern 3 being small, the temperature at the interface between the conductor pattern 3 and the bonding material 12 swiftly rises when heating is performed from below the base plate 11 in Step S5, which reduces the required heating time to melt the bonding material 12, improving manufacturability and productivity. When the thickness of the conductor pattern 3 is 0.8 mm or less, these effects can be obtained more significantly.

As described above, in the method of manufacturing the power semiconductor device of Embodiment 1, in Step S2, the conductor pattern 2 and the semiconductor elements 5 are bonded by melting and solidifying the bonding material 4 and then in Step S2, the conductor pattern 3 and the base plate 11 are bonded by melting and solidifying the bonding material 12, and when bonding the conductor pattern 2 and the base plate 11 in Step S5, heating is performed from below the base plate 11. Heating from below the base plate 11 includes heating by a heat source brought into contact with the lower surface of the base plate 11.

In the semiconductor device 151 of Embodiment 1, the ratio κ₁/D₁ satisfies κ₁/D₁≤35×10⁴W/(m²K) where κ₁ represents the thermal conductivity of the insulating material 1 and D₁ represents the thickness of the insulating material 1, and the solidus temperature of the bonding material 4 is equal to or higher than the solidus temperature of the bonding material 12. Therefore, re-melting of the bonding material 4 is suppressed in Step S5, suppressing deterioration in quality of the semiconductor device 151 due to re-melting of the bonding material 4. In addition, the difference between the solidus temperature of the bonding material 4 and the solidus temperature of the bonding material 12 is within 40° C., this suppresses damage to the insulating material 1 based on the difference between the solidus temperature of the bonding material 4 and the solidus temperature of the bonding material 12, improving the reliability of the semiconductor device 151.

### B. Embodiment 2

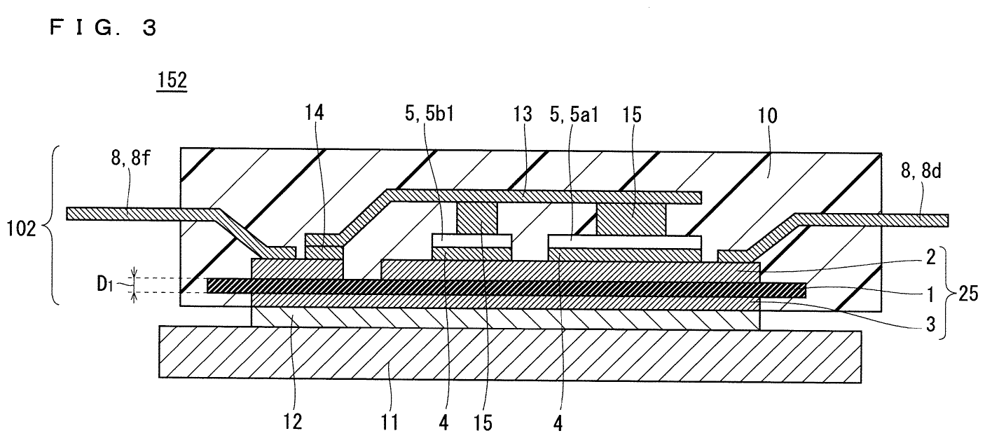

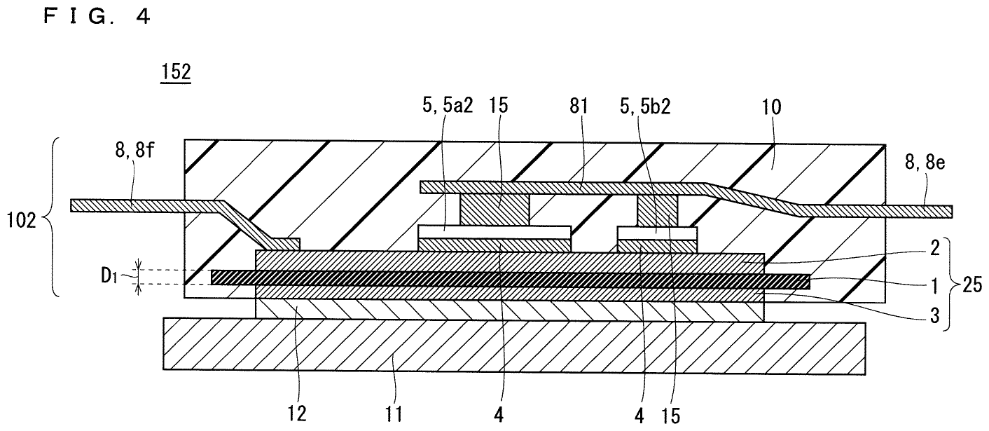

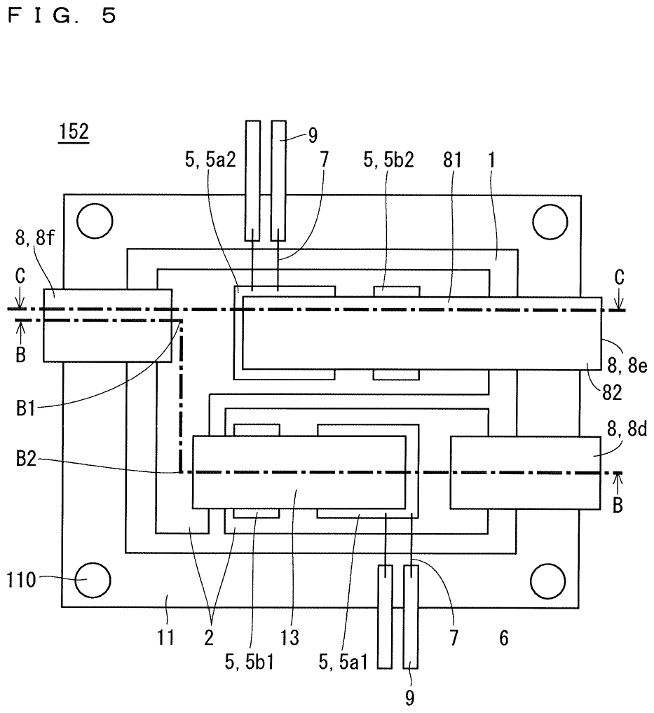

FIG. 5 is a top view of a semiconductor device 152. In order to illustrate the internal structure of the semiconductor device 152, a sealing material 10 included in the semiconductor device 152 is omitted in FIG. 5. FIG. 3 is a cross-sectional view of the semiconductor device 152 of Embodiment 2 and is a cross-sectional view taken along the line B-B in FIG. 5. FIG. 4 is a cross-sectional view of the semiconductor device 152 of Embodiment 2 and is a cross-sectional view taken along the line C-C in FIG. 5.

The difference from the semiconductor device 151 of Embodiment 1 is that the semiconductor device 152 of Embodiment 2 includes a semiconductor unit 102 instead of the semiconductor unit 101. In other respects, the semiconductor device 152 is similar to the semiconductor device 151. The difference from the semiconductor unit 101 is that the semiconductor unit 102 includes an inner lead 13, a main terminal 8d, a main terminal 8e and a main terminal 8f instead of the wire 6, the main terminal 8a, the main terminal 8b, and the main terminal 8c. In other respects, the semiconductor unit 102 is similar to the semiconductor unit 101.

As illustrated in FIG. 3, the inner lead 13 is bonded to the upper surface of the semiconductor element 5a1 by a bonding material 15. The inner lead 13 is bonded to the upper surface of the semiconductor element 5b1 by the bonding material 15. The inner lead 13 is bonded to the upper surface of the semiconductor element 5b1 by the bonding material 14. The conductor pattern 2 and the upper surface of the semiconductor element 5a1 are connected by the inner lead 13. The conductor pattern 2 and the upper surface of the semiconductor element 5b1 are connected by the inner lead 13. The portion of the conductor pattern 2 at which the conductor pattern 2 is bonded with the bonding material 14 is not integral with the portion of the conductor pattern 2 where the semiconductor element 5a1 is bonded with the bonding material 4. The portion of the conductor pattern 2 at which the conductor pattern 2 is bonded with the bonding material 14 is not integral with the portion of the conductor pattern 2 where the semiconductor element 5b1 is bonded with the bonding material 4.

The main terminal 8e includes an inner lead 81 and an outer lead 82. The inner lead 81 is a portion of main terminal 8e that is sealed with the sealing material 10, and is integrated with the outer lead 82, which is a portion of main terminal 8e that projects from the sealing material 10.

The inner lead 81 is bonded to the upper surface of the semiconductor element 5a2 by the bonding material 15. The inner lead 81 is bonded to the upper surface of the semiconductor element 5b2 by the bonding material 15.

The bonding material 14 is, for example, solder. The bonding material 14 is, for example, lead-free solder containing Sn as a main component.

As in the case of the bonding material 4, it is desirable to suppress re-melting of the bonding material 14 and the bonding material 15 during manufacturing. In order to suppress re-melting of the bonding material 14 and the bonding material 15 during manufacturing, the solidus temperature of the bonding material 14 is, for example, higher than the solidus temperature of the bonding material 12, and he solidus temperature of the bonding material 15 is, for example, higher than the solidus temperature of the bonding material 12. If the difference between the solidus temperature of the bonding material 14 and the solidus temperature of the bonding material 12 is within 40° C., damage to the insulating material 1 is suppressed based on the difference between the solidus temperature of the bonding material 14 and the solidus temperature of the bonding material 12, improving the reliability of the semiconductor device 152. If the difference between the solidus temperature of the bonding material 15 and the solidus temperature of the bonding material 12 is within 40° C., damage to the insulating material 1 is suppressed based on the difference between the solidus temperature of the bonding material 14 and the solidus temperature of the bonding material 12, improving the reliability of the semiconductor device 152. The material of the bonding material 14 and the material of the bonding material 15 are, for example, the same as the material of the bonding material 4.

The main terminal 8d is directly connected to the conductor pattern 2. The main terminal 8f is directly connected to the conductor pattern 2. Examples of methods for directly connecting the main terminal 8d and the main terminal 8f to the conductor pattern 2 include ultrasonic (US) bonding and diffusion bonding.

The material of the main terminal 8d, the main terminal 8e, and the main terminal 8f is, for example, the same as the material of the main terminal 8a, the main terminal 8b, and the main terminal 8c of the semiconductor device 151 of Embodiment 1. Also the thickness of the main terminal 8d, the main terminal 8e, and the main terminal 8f is, for example, the same as the thickness of the main terminal 8a, the main terminal 8b, and the main terminal 8c of the semiconductor device 151 of Embodiment 1.

The material of the inner lead 13 is preferably a material with low electrical resistance. The material with low electrical resistance includes, for example, copper, a copper alloy, aluminum, and an aluminum alloy.

Compared to the case of Embodiment 1, the portion where the main current flows through the wires 6 is changed so that the main current flows through the inner lead 13, the main terminal 8d, the main terminal 8e, or the main terminal 8f, thereby reducing electrical resistance and increasing the current capacity of the semiconductor device 152.

FIG. 10 is a flowchart illustrating a method of manufacturing the semiconductor device of Embodiment 2. The method of manufacturing the semiconductor device Embodiment 2 is the same as the method of manufacturing the semiconductor device of Embodiment 1, except that in Step S3, wiring is conducted using the inner lead 13 and the main terminals 8 instead of wiring using wires 6.

### C. Embodiment 3

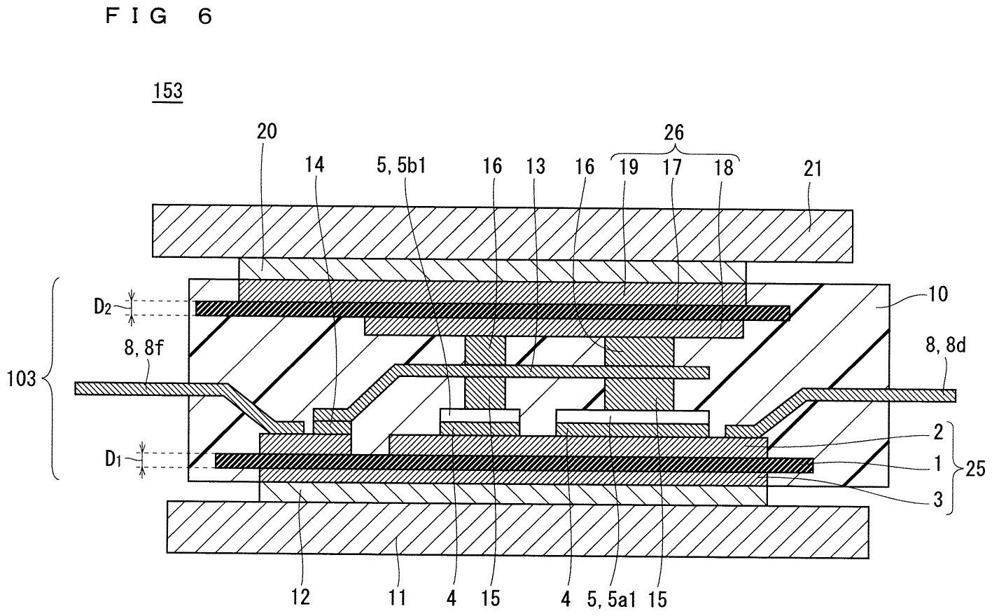

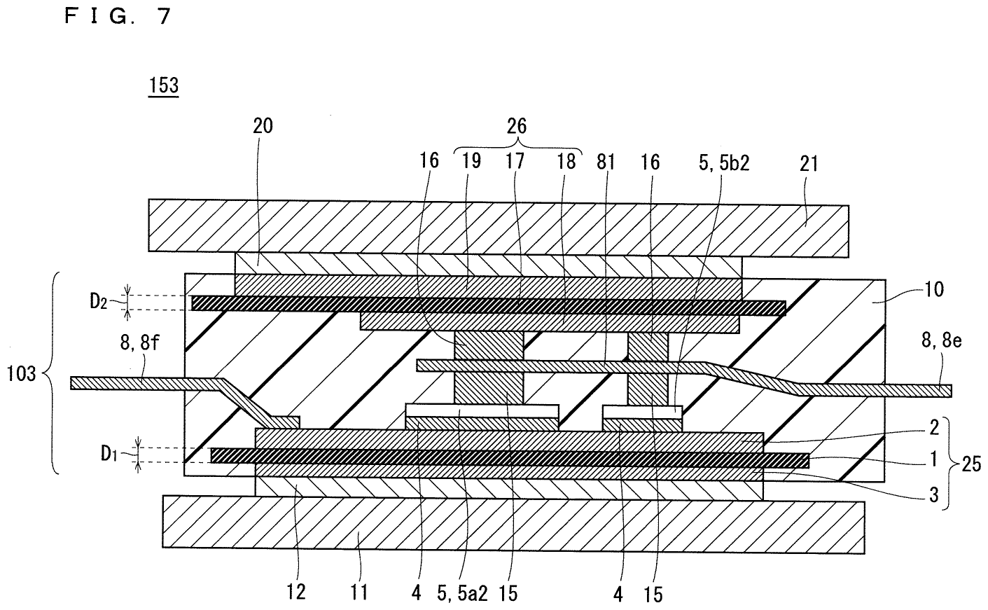

In comparison, the difference from the semiconductor device 152 of Embodiment 2 is that the semiconductor device 153 of Embodiment 3 includes a semiconductor unit 103 instead of the semiconductor unit 102. Also, in the semiconductor device 153, a base plate 21 is bonded to the upper side of the semiconductor unit 103 by a bonding material 20. In other respects, the semiconductor device 153 is similar to the semiconductor device 152. FIG. 6 is a cross-sectional view of the semiconductor device 153 of Embodiment 3 and is a cross-sectional view corresponding to the cross section of the semiconductor device 152 in FIG. 3. FIG. 7 is a cross-sectional view of the semiconductor device 153 of Embodiment 3 and is a cross-sectional view corresponding to the cross section of the semiconductor device 152 in FIG. 4.

Compared to the semiconductor unit 102, the semiconductor unit 103 further includes an insulating substrate 26. In other respects, the semiconductor unit 103 is similar to the semiconductor unit 102. The insulating substrate 26 includes an insulating material 17, a conductor pattern 18, and a conductor pattern 19.

As illustrated in FIG. 6, the conductor pattern 18 is bonded to the upper surface of the inner lead 13 by a bonding material 16. The conductor pattern 18 is bonded to a region of the upper surface of the inner lead 13 that overlaps the semiconductor element 5a1 or the semiconductor element 5b1 in plan view with the bonding material 16.

As illustrated in FIG. 7, the conductor pattern 18 is bonded to the upper surface of the inner lead 81 by a bonding material 16. The conductor pattern 18 is bonded to a region of the upper surface of the inner lead 81 that overlaps the semiconductor element 5a2 or the semiconductor element 5b2 in plan view with the bonding material 16. The insulating material 17 is bonded to the upper surface of the conductor

pattern 18. The conductor pattern 19 is bonded to the upper surface of the insulating material 17. In the semiconductor unit 103, a portion of the conductor pattern 19 is exposed from the sealing material 10. The base plate 2 is in contact with the portion of the conductor pattern 19 exposed from the sealing material 10 via the bonding material

In the semiconductor device 153 of Embodiment 3, a portion of the heat generated from the semiconductor elements 5 is transmitted to the outside of the semiconductor device 153 through the bonding material 15, the inner lead 13, the inner lead 81, the bonding material 16, he conductor pattern 18, the insulation material 17, the conductor pattern 19, the bonding material 20, and the base plate 21. This allows the semiconductor elements 5 to be cooled from both the upper and lower sides, leading to improvement in the current capacity and size reduction in the semiconductor device 153.

The bonding material 16 and the bonding material 20 are, for example, solder. The bonding material 16 and the bonding material 20 are, for example, lead-free solder containing Sn as a main component.

Compared to the method of manufacturing the semiconductor device of Embodiment 1, the method of manufacturing the semiconductor device of Embodiment 3 differs in that, after Step S3 (see FIG. 10) and before Step S4, the insulating substrate 26 is bonded onto the upper surfaces of the inner lead 13 and the inner lead 81 by the bonding material 16, and n Step S5, in addition to bonding the insulating substrate 25 and the base plate 11, the insulating substrate 26 and the base plate 21 are bonded. With respect to other aspects, the method of manufacturing the semiconductor device of Embodiment 3 is the same as the method of manufacturing the semiconductor device of Embodiment 2.

As in the case of the bonding material 4, it is desirable to suppress re-melting of

the bonding material 16 during manufacturing. When bonding the conductor pattern 19 of the insulating substrate 26 and the base plate 21 during manufacturing the semiconductor device 153, the bonding material 20 is placed between the semiconductor unit 103 and the base plate 21, and then the bonding material 20 is melted by heating from above the base plate 21. Therefore, in order to suppress re-melting of the bonding material 16, it is desirable that heat is less easily transferred to the bonding material 16 when heating is performed from above the base plate 21. Also, as in the case of the insulating material 1, it is desirable to suppress damage to the insulating material 17 based on the difference between the solidus temperature of the bonding material 16 and the solidus temperature of the bonding material 20.

A configuration of the semiconductor device 153 is as follows, for example, the ratio κ₂/D₂ satisfies κ₂/D₂≤35×10⁴W/(m²K) where κ₂ represents the thermal conductivity of the insulating material 17 and D₂ represents the thickness of the insulating material 12, the solidus temperature of the bonding material 16 is equal to or higher than the solidus temperature of the bonding material 20, and, the difference between the solidus temperature of the bonding material 16 and the solidus temperature of the bonding material 20 is within 40° C. With this configuration, re-melting of the bonding material 16 is suppressed and damage to the insulating material 17 is suppressed based on the difference between the solidus temperature of the bonding material 16 and the solidus temperature of the bonding material 20.

For example, the thermal conductivity κ₂ of the insulating material 17 is 35 W/(m·K) or less, and the thickness D₂ of the insulating material 17 is 100 μm or more.

The solidus temperature of the bonding material 16 is equal to or higher than the liquidus temperature of the bonding material 20.

The insulating material 17 is, for example, an insulating resin. The insulating

resin is, for example, an insulating resin whose main component is epoxy resin. The insulating material 17 is, for example, ceramic. The ceramic is, for example, a ceramic whose main component is Al₂O₃.

The conductor pattern 19 is thinner than the conductor pattern 18, for example. The thickness of the conductor pattern 19 is, for example, 0.8 mm or less.

The thickness of the bonding material 20 is, for example, 150 μm or less.

### D. Embodiment 4

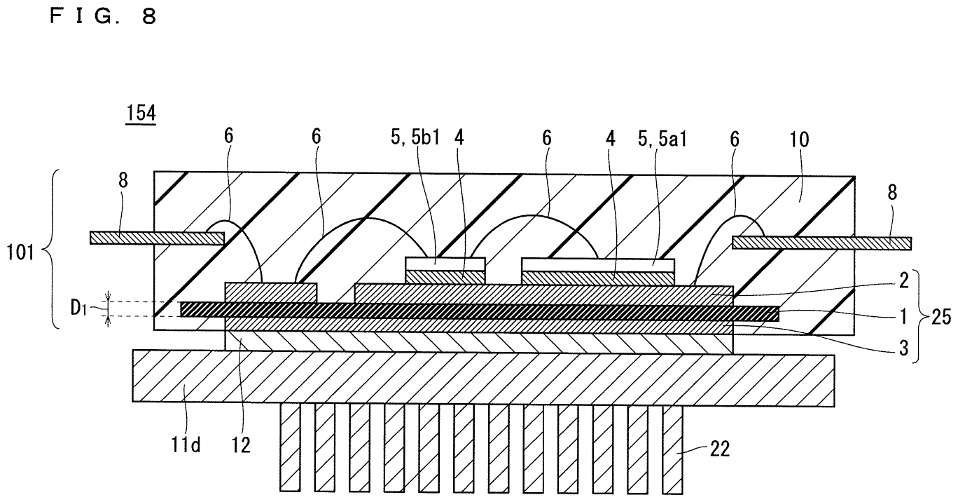

FIG. 8 is a cross-sectional view of a semiconductor device 154 according to Embodiment 4. Compared with the semiconductor device 151 of Embodiment 1, the semiconductor device 154 includes a base plate 11d instead of the base plate 11. In other respects, the semiconductor device 154 is similar to the semiconductor device 151 of Embodiment 1.

The lower surface of the base plate 11d is provided with irregularities. FIG. 8 illustrates a case where the base plate 11d is provided with pin fins 22 on the lower surface thereof, thereby providing irregularities on the lower surface of the base plate 11d. The irregularities on the lower surface of the base plate 11d may be provided by an other structure. For example, the lower surface of the base plate 11d may be provided with irregularities by providing grooves on the lower surface of the base plate 11d.

The irregularities provided on the lower surface of the base plate 11d improves the heat exchange efficiency between the refrigerant and the base plate 11d when the refrigerant is applied directly to the lower surface of the base plate 11d. This allows the semiconductor elements 5 to be efficiently cooled, leading to improvement in the current capacity and size reduction in the semiconductor device 154.

The method of manufacturing the semiconductor device of Embodiment 4 is the same as the method of manufacturing the semiconductor device of Embodiment 1, except that the base plate 11d is used instead of the base plate 11.

The semiconductor device 154 may be a semiconductor device having a configuration in which the base plate 11 in the configuration of the semiconductor device 152 of Embodiment 2 or of the semiconductor device 153 of Embodiment 3 is replaced with the base plate 11d.

### E. Embodiment 5

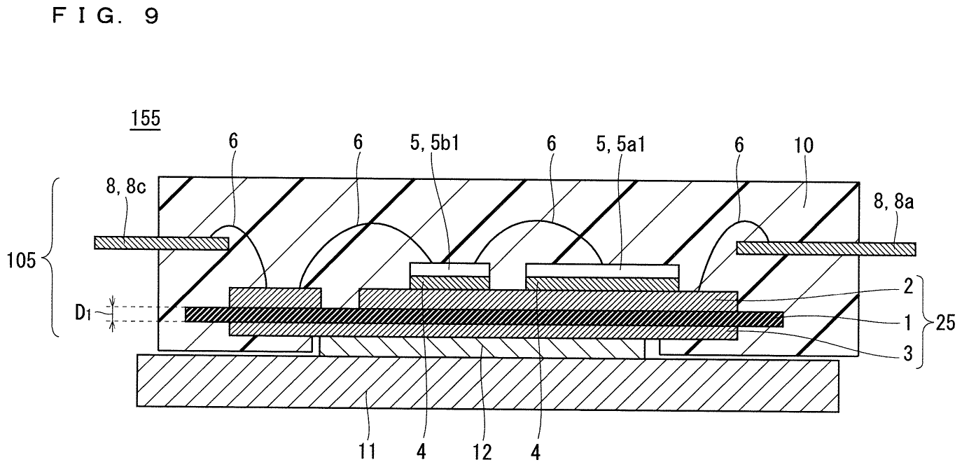

FIG. 9 is a cross-sectional view of a semiconductor device 155 of Embodiment 5. In comparison, the difference from the semiconductor device 151 of Embodiment 1, the semiconductor device 155 of Embodiment 5 includes a semiconductor unit 105 instead of the semiconductor unit 101. In other respects, the semiconductor device 155 of Embodiment 5 is similar to the semiconductor device 151 of Embodiment 1.

In the semiconductor unit 105, the conductor pattern 3 is not bonded to the base plate 11 by the bonding material 12 in at least a partial region of the outer peripheral portion of the lower surface of the conductor pattern 3. Also, in the semiconductor unit 105, the sealing material 10 at least partially covers the outer peripheral portion of the lower surface of the conductor pattern 3. In other respects, the semiconductor unit 105 is similar to the semiconductor unit 101 of Embodiment 1.

The conductor pattern 3 may be bonded to the base plate 11 by the bonding material 12 in at least a partial region of the outer peripheral portion of the lower surface of the conductor pattern 3. The region of the lower surface of the conductor pattern 3 that is not bonded to the base plate 11 by the bonding material 12 may include the entire circumferential direction of the outer periphery of the lower surface of the conductor pattern 3.

The sealing material 10 may partially cover the outer periphery of the conductor pattern 3. The sealing material 10 may entirely cover circumferential direction of the outer periphery of the conductor pattern 3.

With the semiconductor unit 105 and the base plate 11 being bonded by the bonding material 12, a force proportional to the difference ΔT2 between the solidus temperature of the bonding material 12 and room temperature is applied to the conductor pattern 3 from the bonding material 12 at room temperature. The stress generated in the insulating material 1 when the insulating material 1 receives a force, etc. from the bonding material 12 via the conductor pattern 3 tends to be maximized at a portion corresponding to the end portions of the conductor pattern 3. Therefore, possibility of breaks and cracks in the insulating material 1 is high that develop starting from a location corresponding to the end portions of the conductor pattern 3.

In Embodiment 5, the conductor pattern 3 is not bonded to the base plate 11 by the bonding material 12 in at least a partial region of the outer peripheral portion of the lower surface of the conductor pattern 3. Therefore, the stress generated in the portions of the insulating material 1 corresponding to the end portions of the conductor pattern 3 is relaxed, and this suppresses breaks and cracks of the insulating material 1.

The sealing material 10, by covering at least the outer peripheral portion of the conductor pattern 3, also helps relax the stress generated in the portions of the insulating material 1 corresponding to the end portions of the conductor pattern 3, suppressing breaks and cracks of the insulating material 1.

The sealing material 10 and the base plate 11 coming into contact and repelling each other due to temperature changes, causing problems with the bonding by the bonding material 12 is suppressed by leaving a gap between the sealing material 10 and the base plate 11.

A method of manufacturing the semiconductor device of Embodiment 5 is the same as the method of manufacturing the semiconductor device of Embodiment 1, except that the sealing material 10 seals so as to at least partially cover the outer peripheral portion of the lower surface of the conductor pattern 3.

### E. Embodiment 6

In Embodiment 6, the semiconductor device according to any one of Embodiments 1 to 5 described above is applied to a power conversion apparatus. While application of the semiconductor device according to any one of Embodiments 1 to 5 is not limited to a specific power conversion apparatus, hereinafter, as Embodiment 6, the semiconductor device according to any one of Embodiments 1 to 5 is applied to a three-phase inverter will be described.

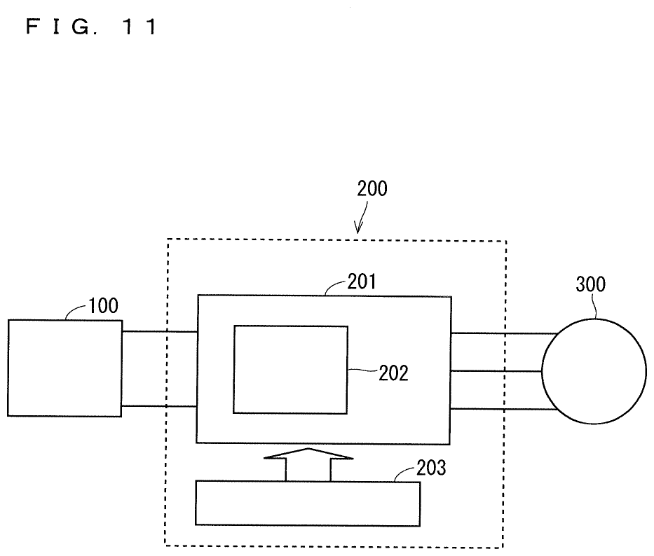

FIG. 11 is a block diagram illustrating a configuration a power conversion system to which a power conversion apparatus according to Embodiment 6 is applied.

The power conversion system illustrated in FIG. 11 includes a power source 100, a power conversion apparatus 200, and a load 300. The power source 100 is a DC power source and supplies DC power to the power conversion apparatus 200. The power source 100 can be configured by various forms including, for example, a DC system, a solar battery, a storage battery, and a rectifier circuit or an AC/DC converter connected to an AC system. Further, the power source 100 may be configured by a DC/DC converter that converts DC power output from a DC system into predetermined power.

The power conversion apparatus 200, being a three-phase inverter connected between the power source 100 and the load 300, converts DC power supplied from the power source 100 into AC power, and supplies AC power to the load 300. As illustrated in FIG. 11, the power conversion apparatus 200 includes a main conversion circuit 201 that converts DC power into AC power and outputs the AC power, and a control circuit 203 that outputs a control signal for controlling the main conversion circuit 201 to the main conversion circuit 201.

The load 300 is a three-phase electric motor driven by AC power supplied from the power conversion apparatus 200. Note that the load 300 is not limited to a specific application, and is an electric motor installed in various electrical devices, and is used, for example, as an electric motor for a hybrid vehicle, an electric vehicle, a railway vehicle, an elevator, or an air conditioner.

Hereinafter, the details of the power conversion apparatus 200 will be described below. The main conversion circuit 201 includes a switching element and a freewheeling diode (not illustrated), and when the switching element performs switching, the main conversion circuit 201 converts DC power supplied from the power source 100 into AC power, and supplies the AC power to the load 300. Although there are various specific circuit configurations for the main conversion circuit 201, the main conversion circuit 201 according to Embodiment 6 is a two-level three-phase full bridge circuit, and configured by six switching elements and six freewheeling diodes each connected in antiparallel to the switching elements. At least any of each switching element and each freewheeling diode of the main conversion circuit 201 is a switching element or a freewheeling diode included in the semiconductor device 202, which corresponds to the semiconductor device according to any one of Embodiments 1 to 5 described above. The six switching elements are connected in series in pairs to form upper and lower arms, with each upper and lower arm constituting each phase (U-phase, V-phase, W-phase) of the full bridge circuit. The output terminal of each of the upper and lower arms, that is, the three output terminals of the main conversion circuit 201, are connected to the load 300.

Also, the main conversion circuit 201 includes a drive circuit (not illustrated) that drives each switching element, and the drive circuit may be built in the semiconductor device 202 or may be provided separately from the semiconductor device 202. The drive circuit generates a drive signal for driving the switching element of the main conversion circuit 201 and supplies the driving signal to the control electrode of the switching element of the main conversion circuit 201. Specifically, in response to a control signal from the control circuit 203, which will be described later, a drive signal that turns the switching element on and a drive signal that turns the switching element off are output to the control electrode of each switching element. When keeping the switching element in the on state, the drive signal is a voltage signal (on signal) that is equal to or greater than a threshold voltage of the switching element, and when keeping the switching element in the off state, the drive signal is a voltage signal (off signal) that is equal to or less than the threshold voltage of the switching element.

The control circuit 203 controls switching elements of main conversion circuit 201 so that desired power is supplied to the load 300. Specifically, based on the power to be supplied to the load 300, the time (on time) during which each switching element of the main conversion circuit 201 should be in the on state is calculated. For example, the main conversion circuit 201 can be controlled by PWM control that modulates the on time of the switching element according to the voltage to be output. Then, a control command (control signal) is output to the drive circuit included in the main conversion circuit 201 so that an on signal is output to the switching element that should be in the on state at each time, and an off signal is output to the switching element that should be in the off state. The drive circuit outputs an on signal or an off signal as a drive signal to the control electrode of each switching element according to the control signal.

In the power conversion apparatus according to Embodiment 6, the semiconductor device according to any one of Embodiments 1 to 5 is applied as the semiconductor device 202 included in the main conversion circuit 201; therefore, re-melting of the bonding material 4 during the manufacturing process of the semiconductor device 202 can be suppressed, and deterioration in the quality of the power converter device can be suppressed.

In Embodiment 6, while an example has been described in which the semiconductor device according to any one of Embodiments 1 to 5 is applied to a two-level three-phase inverter, the application of the semiconductor device according to any one of Embodiments 1 to 5 is not limited thereto, and can be applied to various power conversion apparatuses. In Embodiment 6, a 2-level power conversion apparatus is adopted, but a 3-level or multi-level power conversion apparatus may also be adopted, and further, the semiconductor device according to any one of 1 to 5 may be applied to a single-phase inverter when supplying power to a single-phase load. Further, when power is supplied to a DC load or the like, the semiconductor device according to any one of Embodiments 1 to 5 can be applied to a DC/DC converter or an AC/DC converter.

Further, the power conversion apparatus to which the semiconductor device according to any one of Embodiments 1 to 5 is applied is not limited to the case where the above-mentioned load is an electric motor, but is applicable to, for example, a power source device for electrical discharge machines, laser processing machines, induction heating cookers, or non-contact power supply systems, further, is used a power conditioner for solar power generation systems, power storage systems, and the like.

It should be noted that Embodiments can be arbitrarily combined and can be appropriately modified or omitted.

### EXPLANATION OF REFERENCE SIGNS

1 insulating material, 2, 3, 18, 19 conductor pattern, 4, 12, 14, 15, 16, 20 bonding material, 5, 5a1, 5a2, 5b1, 5b2 semiconductor element, 6, 7 wire, 8 main terminal, 8a, 8b, 8c, 8d, 8e, 8f main terminal, 9 signal terminal, 10 sealing material, 11, 11D21 base plate, 13, 81 inner lead, 17 insulating material, 22 pin fin, 25, 26 insulating substrate, 82 outer lead, 100 power source, 101, 102, 103, 105 semiconductor unit, 151, 152, 153, 154, 155, 202 semiconductor device, 200 power conversion apparatus, 201 main conversion circuit, 203 control circuit, 300 load.

1. A semiconductor device comprising:
a first insulating material having an upper surface and a lower surface;
a first conductor pattern provided on the upper surface of the first insulating material;
a second conductor pattern provided on the lower surface of the first insulating material;
a semiconductor element bonded to an upper surface of the first conductor pattern by a first bonding material; and
a first base plate bonded to a lower surface of the second conductor pattern by a second bonding material, wherein
a ratio κ1/D1 satisfies κ1/D1≤35×104W/(m2K) where κ₁ represents thermal conductivity of the first insulating material and D1 represents a thickness of the first insulating material,
solidus temperature of the first bonding material is equal to or higher than solidus temperature of the second bonding material, and
a difference between the solidus temperature of the first bonding material and the solidus temperature of the second bonding material is within 40° C.

2. The semiconductor device according to claim 1, wherein the solidus temperature of the first bonding material is equal to or higher than liquidus temperature of the second bonding material.

3. The semiconductor device according to claim 1, wherein
the thermal conductivity κ₁ of the first insulating material is 35 W/(m·K) or less, and
the thickness D1 of the first insulating material is 100 μm or more.

4. The semiconductor device according to claim 1, wherein
the first bonding material is solder, and
the second bonding material is solder.

5. The semiconductor device according to claim 1, wherein
the first insulating material includes ceramic.

6. The semiconductor device according to claim 1, wherein
the first insulating material includes an insulating resin.

7. The semiconductor device according to claim 1, wherein
the second conductor pattern is thinner than the first conductor pattern.

8. The semiconductor device according to claim 1, wherein
the second conductor pattern is 0.8 mm or less in thickness.

9.-10. (canceled)

11. The semiconductor device according to claim 1, wherein
the second conductor pattern is not bonded to the first base plate by the second bonding material in at least a partial region of an outer peripheral portion of the lower surface of the second conductor pattern.

12. The semiconductor device according to claim 1, further comprising
a sealing material that seals the semiconductor element.

13. The semiconductor device according to claim 12, wherein
a linear thermal expansion coefficient of the sealing material is equal to or less than the linear thermal expansion coefficient of the second bonding material.

14. The semiconductor device according to claim 12, wherein
the sealing material at least partially covers the outer peripheral portion of the lower surface of the second conductor pattern.

15. The semiconductor device according to claim 1, further comprising
an inner lead, wherein
the inner lead is bonded to an upper surface of the semiconductor element by a third bonding material.

16. The semiconductor device according to claim 15, wherein
solidus temperature of the third bonding material is equal to or higher than solidus temperature of the second bonding material, and
a difference between the solidus temperature of the third bonding material and the solidus temperature of the second bonding material is within 40° C.

17.-18. (canceled)

19. The semiconductor device according to claim 15, further comprising
a second insulating material, a third conductor pattern, a fourth conductor pattern, and a second base plate, wherein
the third conductor pattern is provided on a lower surface of the second insulating material,
the fourth conductor pattern is provided on an upper surface of the second insulating material,
the third conductor pattern is bonded to an upper surface of the inner lead by a fifth bonding material, and
the second base plate is bonded to an upper surface of the fourth conductor pattern by a sixth bonding material.

20. The semiconductor device according to claim 19, wherein
a ratio κ2/D2 satisfies κ2/D2≤35×104W/(m2K where κ2 represents thermal conductivity of the second insulating material and D2 represents a thickness of the second insulating material,
solidus temperature of the fifth bonding material is equal to or higher than solidus temperature of the sixth bonding material, and
a difference between the solidus temperature of the fifth bonding material and the solidus temperature of the sixth bonding material is within 40° C.

21. The semiconductor device according to claim 20, wherein
the solidus temperature of the fifth bonding material is equal to or higher than liquidus temperature of the sixth bonding material.

22. The semiconductor device according to claim 20, wherein
the fourth conductor pattern is thinner than the third conductor pattern.

23. The semiconductor device according to claim 20, wherein
the fourth conductor pattern is 0.8 mm or less in thickness.

24. (canceled)

25. A power conversion apparatus comprising:
a main conversion circuit including the semiconductor device according to claim 1; and
a control circuit, wherein
the main conversion circuit converts input power and outputs the power, and
the control circuit outputs a control signal for controlling the main conversion circuit to the main conversion circuit.

26. (canceled)
